(19) United States
(12) Patent Application Publication
(10) Pub. No.: US 2002/0127766 A1
(43) Pub. Date: Sep. 12, 2002

(54) Semiconductor wafer manufacturing process

(75) Inventors: Michael J. Ries, St. Charles, MO (US); Gregory M. Wilson, Chesterfield, MO (US); Robert W. Standley, Chesterfield, MO (US); Larry W. Shive, St. Peters, MO (US); Jon A. Rossi, Chesterfield, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/036,917

(22) Filed: Dec. 21, 2001

Related U.S. Application Data
(60) Provisional application No. 60/258,414, filed on Dec. 27, 2000.

(51) Int. Cl. H01L 21/00; C30B 23/00; C30B 28/12; C30B 25/00; C30B 28/14

(52) U.S. Cl. 438/94

(57) ABSTRACT

A process for manufacturing a semiconductor wafer comprises first etching the wafer to reduce damage on the front and back surfaces. An epitaxial layer is grown on the etched front surface of the semiconductor wafer to improve the surface roughness of the front surface. Finally, the front surface of the wafer is final polished to further improve the surface roughness of the front surface.

### CROSS-REFERENCE TO RELATED APPLICATION

This application claims priority from U.S. patent application Ser. No. 60/258,414 (provisional), filed Dec. 27, 2000, which is hereby incorporated by reference.

### BACKGROUND OF THE INVENTION

The present invention relates to a process for manufacturing semiconductor wafers. More particularly, the present invention relates to a simplified process for manufacturing high quality semiconductor wafers having an epitaxial silicon layer on the front surface.

Single crystal silicon is the starting material for most processes for the fabrication of semiconductor electronic components and is commonly prepared with the so-called Czochralski process. In this process, a crystal pulling apparatus purged with a continuous stream of argon is utilized wherein polycrystalline silicon (“polysilicon”) is charged to a quartz crucible with or without dopant, the polysilicon is melted, a seed crystal is immersed into the molten silicon and a single crystal silicon ingot is grown by slow extraction while the crucible is rotated.

Once a single silicon ingot is grown and shaped, it is generally sliced into individual wafers and refined by etching and/or lapping and grinding to increase the wafer flatness. Generally, the substrate edges are rounded and the wafer chemically etched to reduce any surface damage and contamination caused by prior processing steps. Finally, the wafers are polished on one or both sides and an epitaxial silicon layer deposited on the front surface of the wafer to provide a semiconductor wafer suitable for device fabrication. At various points in the manufacturing process the wafer can be treated such that its gettering capabilities are increased.

To increase overall throughput of single crystal silicon ingots and reduce cost, it is desirable to grow and cool the single crystal silicon ingots as quickly as possible, while attempting to limit the amount and type of defects generated by faster cooling times. During fast cooling of fast pull or continuous pull single silicon crystals (i.e., crystals grown under vacancy rich conditions) agglomeration of vacancies results in the formation of small voids on the crystal that are exposed during the subsequent wafering processes and ultimately detected on semiconductor wafers as crystal originated pits/particles (COPs), surface defects, dislocations, and oxidation-induced stacking faults (OSF). These defects can severely degrade the performance of circuits fabricated on the wafer, and can make the wafer unfit for grade 1 product.

Several methods have been suggested to minimize or eliminate these problems including utilizing crystal pulling processes that can produce single silicon ingots with large areas substantially free from crystal voids and other defects. Although this method does substantially eliminate many of the above-described defects, it is a slow and costly process. Another approach disclosed by Adachi (U.S. Pat. No. 5,931,662) utilizes various high temperature annealing steps in different gas atmospheres to smooth the wafer surface and reduce the number of COPs on the wafer surface.

This approach adds additional processing steps and requires costly equipment to implement. Another approach in the art to reduce grown in defects such as COPs on the front surface of a semiconductor wafer is to grow an epitaxial silicon layer on the front surface of a polished semiconductor wafer. The deposition of a few microns of epitaxial silicon on the front surface of a polished semiconductor wafer causes the surface to restructure and typically eliminates substantially all of the COPs on the wafer surface. The use of silicon wafers having an epitaxial silicon layer to reduce or eliminate COPs and other grown in defects to date has been a costly option as the epitaxial layer is grown on a polished surface to ensure the control of potential nanotopology problems. The polishing of the front surface is one of the most expensive and time consuming steps of the manufacturing process.

To date, the prior art has failed to disclose a completely satisfactory method for reducing or eliminating the number of COPs on the front surface of a semiconductor wafer at a reasonable cost without additional processing steps. As such, a there is a need in the semiconductor industry for a simple, low cost process of producing semiconductor wafers having a substantially defect-free front surface such that devices may be fabricated on that surface.

### SUMMARY OF THE INVENTION

Among the objects of the present invention, therefore, are the provision of a process for producing a low cost semiconductor wafer having an epitaxial silicon layer; the provision of a process for growing an epitaxial silicon layer directly on an etched semiconductor surface; the provision of a process that produces a semiconductor wafer having an epitaxial silicon layer with reduced polishing steps; and the provision of a process for producing a semiconductor wafer substantially free of COPs.

Briefly, the present invention is directed to a process for manufacturing a semiconductor wafer sliced from a single crystal ingot. The process comprises first etching the wafer to reduce damage on the front and back surfaces. An epitaxial layer is grown on the etched front surface of the semiconductor wafer to improve the surface roughness of the front surface. Finally, the front surface of the wafer is final polished to further improve the surface roughness of the front surface.

In another aspect, the present invention is directed to a process for manufacturing a semiconductor wafer comprising etching the semiconductor wafer to reduce damage on the front and back surfaces, cleaning the etched front surface to remove metals, particulate matter and a silicon oxide layer therefrom, and growing a layer of epitaxial silicon on the cleaned and etched front surface to improve the surface roughness of the front surface. The method further comprises subjecting the semiconductor wafer to a process for creating a denuded zone within the wafer and final polishing the front surface of the epitaxial wafer to improve the surface roughness of the front surface.

Other objects and features of this invention will be in part apparent and in part pointed out hereinafter.

### BRIEF DESCRIPTION OF THE DRAWINGS

FIG. 1 is a flow diagram showing a preferred embodiment of the present invention,

FIG. 2 is a flow diagram of a second preferred embodiment of the invention,

FIG. 3 is a graph of the critical radius verses temperature for various interstitial oxygen concentrations, and

FIG. 4 is a schematic depiction of the non-isothermal oxygen precipitate nucleation and stabilization heat treatment.

### DETAILED DESCRIPTION OF THE PREFERRED EMBODIMENTS

In accordance with the present invention, it has been discovered that low-cost, high quality semiconductors wafers having an epitaxial layer on the front surface can be produced in a simplified manufacturing process wherein the epitaxial silicon layer is grown directly onto an etched semiconductor surface followed by a final polish. Surprisingly, it has been shown that perturbations in the geometry of the epitaxial silicon layer due to the surface roughness of the etched surface which can interfere with patterning during device manufacturing are substantially eliminated by the final polishing. Advantageously, the semiconductor wafer of the present invention can also be subjected to a process for increasing the internal gettering capabilities of the wafer without adversely effecting the epitaxial layer.

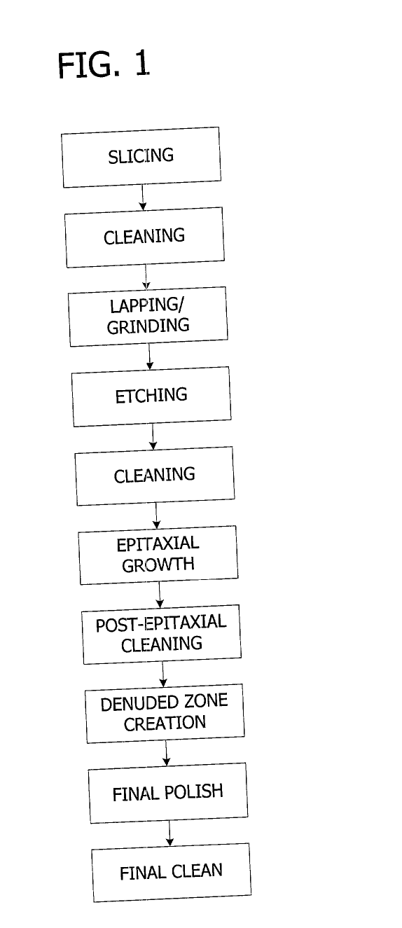

Referring now to FIG. 1, there is shown a flow chart detailing the process steps of the present invention to produce low cost semiconductor wafers having an epitaxial layer on the front surface. As indicated in FIG. 1, the semiconductor wafer is sliced from a single-crystal ingot which may or may not contain a p-type or n-type dopant utilizing a conventional internal diameter saw or wire saw to produce a thin wafer disk having a predetermined initial thickness. The wafer has a front surface and a back surface, and an imaginary central plane between the front and back surfaces. The terms “front” and “back” in this context are used to distinguish the two major, generally planar surfaces of the wafer. The front surface for purposes of this invention is the surface upon which the epitaxial layer is deposited and upon which electronic devices are ultimately printed. The initial thickness of each semiconductor wafer is substantially greater than the desired end thickness of the finished wafer to allow subsequent processing operations to reduce the thickness of the wafer without the risk of damaging or fracturing the wafer. For example, the initial thickness of the semiconductor wafer may be between about 800 and about 1200 microns. Semiconductor wafers suitable for use in the present invention include p(+), p(−), n(+) and n(−) semiconductor wafers.

After slicing, the semiconductor wafer is generally subjected to a conventional cleaning operation to remove particulate matter deposited on the wafer during the slicing operation. This cleaning process may include sequential tanks of etching solution, cleaning solution and water rinses. Approximately 2 to 10 microns of material is removed from both the front and the back surfaces of the semiconductor wafer during cleaning. At this stage of the manufacturing process, the peripheral edge of the wafer may also be profiled by a conventional edge grinder to reduce the risk of damage to the wafer during further processing. The wafer is generally cleaned after profiling in a similar manner as described above. The wafer may then be optionally marked by laser for identification prior to the next operation.

Referring again to FIG. 1, the wafer is next subjected to a conventional lapping and/or grinding operation to lessen the waviness and surface damage on the wafer generated from ingot slicing. The lapping and/or grinding operation generally removes between about 40 microns and about 80 microns, preferably about 60 microns of material from the wafer. After the conventional lapping and/or grinding operation the wafer generally has a TTV of between about 0.5 microns and about 1.5 microns and a surface roughness (R_{A}) of between about 0.1 microns and about 0.5 microns over an area of 1 millimeter by 1 millimeter. It will be recognized by one skilled in the art that conventional lapping and/or grinding techniques are well known in the industry and various methods can be utilized to carry out the operation.

Again referring the FIG. 1, the wafer is next subjected to an etching operation in which the wafer is immersed in a chemical etchant to further reduce the thickness of the wafer and to further remove damage remaining on the semiconductor wafer surfaces. Conventional etching techniques such as acidic or alkaline immersion etching wherein the semiconductor wafer is completely immersed in an etchant solution for a short period of time generally on the order of about 1 minute to about 7 minutes are in accordance with the present invention. After the etching operation is complete, the semiconductor wafer generally has a TTV of between about 1 micron and about 4 microns, more preferably about 2.5 microns and an average front surface roughness (R_{A}) of between about 50 nanometers and about 100 nanometers over an area of 1 millimeter by 1 millimeter, preferably about 75 nanometers over an area of 1 millimeter by 1 millimeter. The conventional immersion etching techniques generally remove about 40 microns of material total from the semiconductor wafer, or about 20 microns from the front and about 20 microns from the back surface. It would be recognized by one skilled in the art that other etching techniques, such as plasma etching or micro-etching may also be used in accordance with the present invention.

After the etching operation is complete, the wafer is subjected to a two-step pre-epitaxial deposition cleaning operation. The first step is a wet cleaning operation to remove metals and particulates wherein both surfaces are cleaned using a conventional solution such as piranha mixtures (i.e., mixtures of sulfuric acid and hydrogen peroxide), SC-1 mixtures, and SC-2 mixtures. The second step cleans the front surface of the semiconductor wafer and removes any native silicon oxide layer (i.e., a silicon oxide layer which forms on a silicon surface and generally has a thickness of from about 10 to about 15 angstroms) for epitaxial silicon deposition. Any silicon oxide layer preferably is completely removed from the front surface of the wafer before the epitaxial layer is deposited onto the surface. As used herein, the phrase “silicon oxide layer” refers to a layer of silicon atoms which are chemically bound to oxygen atoms.

In a preferred second step of the cleaning method in accordance with the present invention, cleaning of the front surface and removal of the silicon oxide layer is accomplished by heating the surface of the wafer in an oxidant-free atmosphere until the silicon oxide layer is removed from the surface. More particularly, the surface of the wafer is preferably heated to a temperature of at least about 1100° C., and more preferably to a temperature of at least about 1150° C. This heating preferably is conducted while exposing the surface of the wafer to an atmosphere comprising a noble gas (e.g., He, Ne, or Ar) or H₂. Most preferably, the atmosphere consists essentially of H₂because use of other atmospheres may tend to cause etch pits to form in the surface of the wafer. Conventional pre-epitaxial deposition cleaning operations, which remove a silicon oxide layer by heating a wafer in the presence of H₂, include heating the wafer to a high temperature (e.g., from about 1000 to about 1250° C.) and then baking the wafer at that temperature for a period of time (e.g., typically up to about 90 seconds). During the removal of the silicon oxide layer, the wafer preferably is heated at a rate which does not introduce thermal gradients which may cause slip.

After the pre-epitaxial cleaning operation is complete and the native oxide layer removed, an epitaxial silicon layer is deposited directly onto the cleaned, etched front surface of the semiconductor. In accordance with the present invention, the epitaxial deposition preferably is carried out by chemical vapor deposition in a batch operation. In a preferred embodiment of this invention, the surface of the wafer is exposed to an atmosphere comprising a volatile gas comprising silicon (e.g., SiCl₄, SiHCl₃, SiH₂Cl₂, SiH₃Cl, or SiH₄) . The atmosphere also preferably contains a carrier gas (preferably H₂) . In one embodiment, the source of silicon during the epitaxial deposition is SiH₂Cl₂ or SiH₄. If SiH₂Cl₂ is used, the reactor pressure during deposition preferably is from about 500 to about 760 Torr. If, on the other hand, SiH₄ is used, the reactor pressure preferably is about 100 Torr. Most preferably, the source of silicon during the deposition is SiHCl₃. This tends to be much cheaper than other sources. In addition, an epitaxial deposition using SiHCl₃ may be conducted at atmospheric pressure. This is advantageous because no vacuum pump is required and the reactor chamber does not have to be as robust to prevent collapse. Moreover, fewer safety hazards are presented and the chance of air leaking into the reactor chamber is lessened.

During the epitaxial deposition, the temperature of the wafer surface preferably is maintained at a temperature sufficient to prevent the atmosphere comprising silicon from depositing polycrystalline silicon on the surface. Generally, the temperature of the surface during this period preferably is at least about 800° C.

The rate of growth of the epitaxial silicon on the etched surface is preferably from about 3.5 to about 4.0 microns/min when the deposition is conducted under atmospheric pressure. This may be achieved by, for example, by using an atmosphere consisting essentially of about 2.5 mole % SiHCl₃ and about 97.5 mole % H₂ at a temperature of about 1150° C. and a pressure of about 1 atm. In accordance with the present invention, an epitaxial layer is grown on the front surface to a thickness of between about 0.5 microns and about 100 microns, more preferably between about 1 micron and about 10 microns. The thickness variance is preferably no more than about 10%, more preferably no more than about 5%.

If the intended use of the wafer requires that the epitaxial layer include a dopant, the atmosphere comprising silicon also preferably contains the dopant. For example, it is often preferable for the epitaxial layer to contain boron. Such a layer may be prepared by, for example, including B₂H₆ in the atmosphere during the deposition. The mole fraction of B₂H₆ in the atmosphere needed to obtain the desired properties (e.g., resistivity) will depend on several factors, such as the amount of boron out-diffusion from the particular substrate during the epitaxial deposition, the quantity of p(−) type dopants that are present in the reactor and substrate as contaminants, and the reactor pressure and temperature. Applicants have successfully used an atmosphere containing about 0.03 ppm of B₂H₆ (i.e., about 0.03 mole of B₂H₆ per 1,000,000 moles of total gas) at a temperature of about 1125° C. and a pressure of about 1 atm. to obtain an epitaxial layer having a resistivity of about 10 Ω-cm.

Once an epitaxial layer having the desired thickness has been formed, the atmosphere comprising silicon preferably is purged with a noble gas (e.g., Ar, Ne, or He) or H₂, and most preferably is purged with H₂. Afterward, the wafer preferably is cooled to a temperature of no greater than 700° C. and then removed from the epitaxial deposition reactor.

After the epitaxial silicon layer has been grown on the front surface of the wafer, the wafer may optionally be subjected to a conventional post-epitaxial cleaning step to remove byproducts formed during the epitaxial deposition.

This step is used to prevent time-dependent haze, which results if such byproducts react with air. In addition, many post-epitaxial cleaning techniques tend to form a silicon oxide layer on the epitaxial surface which tends to passivate (i.e., protect) the surface. Conventional post-epi cleaning methods entail, for example, immersing the epitaxial surface in any of a number of cleaning solutions which are well-known to those of ordinary skill in the art. These solutions include, for example, piranha mixtures (i.e., mixtures of sulfuric acid and hydrogen peroxide), SC-1 mixtures, and SC-2 mixtures. Many such post-epi cleaning steps require about 5 minutes to complete.

After the epitaxial silicon deposition or the optional post-epitaxial cleaning operation, the wafer may optionally be subjected to a process for creating a denuded zone (i.e. a non-uniform depth distribution of oxygen precipitates) of sufficient depth and a wafer bulk containing a sufficient density of oxygen precipitates for internal gettering during device manufacturing. To create a semiconductor wafer having a denuded zone and wafer bulk containing oxygen precipitates for internal gettering several steps are required.

First, the wafer is subjected to a heat-treatment or rapid thermal annealing step in which the wafer is heated to an elevated temperature to form and thereby increase the number density of crystal lattice vacancies in the wafer.

Preferably, this annealing step is carried out in a rapid thermal annealer in which the wafer is rapidly heated to a target temperature and annealed at that temperature for a relatively short period of time. Note that the annealing step may be performed in the same machine used to deposit the epitaxial layer. In general, the wafer is subjected to a temperature in excess of 1150° C., preferably at least 1175° C., more preferably at least about 1200° C., and most preferably between about 1200° C. and 1275° C.

The rapid thermal annealing step is carried out in the presence of an atmosphere containing argon, nitrogen or oxygen, or some mixture thereof. An increase in vacancy concentration throughout the wafer is achieved nearly, if not immediately, upon achieving the annealing temperature; annealing the wafer at this temperature in the argon and/or nitrogen atmosphere will further increase the vacancy concentration. Thus, the wafer will generally be maintained at this temperature for at least one second, typically for at least several seconds (e.g., at least 3) or even several tens of seconds and, depending upon the desired characteristics of the wafer and the atmosphere in which the wafer is being annealed, for a period which may range up to about 60 seconds (which is near the limit for commercially available rapid thermal annealers).

In general, annealing the wafer in a rapid thermal annealer in the presence of an argon or nitrogen atmosphere produces a non-uniform vacancy concentration (number density) profile in the wafer with the peak concentration occurring within about 50 to 100 microns of the surface which is exposed to the argon or nitrogen gas and a lesser and relatively uniform concentration in the wafer bulk. If the front and back surfaces of the wafer are exposed to the gas atmosphere during the rapid thermal annealing step, therefore, the resulting wafer will have a vacancy concentration (number density) profile which is generally “U-shaped” for a cross-section of the wafer, that is, a maximum concentration will occur within several microns of each of the front and back surfaces and a relatively constant and lesser concentration will occur throughout the wafer bulk.

Experimental evidence obtained to-date suggests that the atmosphere in which the rapid thermal annealing step is carried out should have an essential absence of oxygen in order for the build-up of vacancies to occur. That is, the atmosphere should have a total absence of oxygen or a partial pressure of oxygen which is insufficient to inject sufficient quantities of silicon self-interstitial atoms which suppress the build-up of vacancy concentrations. The lower limit of oxygen concentration has been determined to be about 500 ppm. It has also been demonstrated that for oxygen concentrations up to about 2000 ppm no increase in vacancy concentration is observed.

In addition to causing the formation of crystal lattice vacancies, the rapid thermal annealing step causes the dissolution of any unstabilized oxygen precipitate nucleation centers which are present in the silicon starting material. These nucleation centers may be formed, for example, during the growth of the single crystal silicon ingot from which the wafer was sliced or as a consequence of some other event in the previous thermal history of the wafer or of the ingot from which the wafer is sliced. Thus, the presence or absence of these nucleation centers in the starting material is not critical, provided these centers are capable of being dissolved during the rapid thermal annealing step.

The rapid thermal anneal may be carried out in any of a number of commercially available rapid thermal annealing (“RTA”) furnaces in which wafers are individually heated by banks of high power lamps. RTA furnaces are capable of rapidly heating a silicon wafer, e.g., they are capable of heating a wafer from room temperature to 1200° C. in a few seconds. One such commercially available RTA furnace is the model SHS 2800 furnace available from Mattson Technology, Fremont, Calif.

Crystal lattice vacancies, like metals and other elements, are capable of diffusing through single crystal silicon with the rate of diffusion being temperature dependent. For example, crystal lattice vacancies are relatively mobile at temperatures in the vicinity of the temperature at which the wafer is annealed in the rapid thermal annealing step whereas they are essentially immobile for any commercially practical time period at temperatures of as much as 700° C. Experimental evidence obtained to-date suggests that the diffusion rate of vacancies slows considerably at temperatures less than about 700° C. and perhaps as great as 800° C., 900° C., or even 1,000° C., the vacancies can be considered to be immobile for any commercially practical time period.

Upon completion of the rapid thermal annealing, the wafer is rapidly cooled through the range of temperatures at which crystal lattice vacancies are relatively mobile in the single crystal silicon. As the temperature of the wafer is decreased through this range of temperatures, the vacancies diffuse to the oxide layer and become annihilated, thus leading to a change in the vacancy concentration profile with the extent of change depending upon the length of time the wafer is maintained at a temperature within this range. If the wafer were held at this temperature within this range for an infinite period of time, the vacancy concentration would once again become substantially uniform throughout the wafer bulk with the concentration being an equilibrium value which is substantially less than the concentration of crystal lattice vacancies immediately upon completion of the heat treatment step. By rapidly cooling the wafer, however, a non-uniform distribution of crystal lattice vacancies can be achieved with the maximum vacancy concentration being at or near central plane of the wafer and the vacancy concentration decreasing in the direction of the front surface and back surface of the wafer. In general, the average cooling rate within this range of temperatures is at least about 5° C. per second, preferably at least about 20° C. per second, more preferably at least about 50° C. per second, still more preferably at least about 100° C. per second, with cooling rates in the range of about 100° C. to about 200° C. per second being presently most preferred. Once the wafer is cooled to a temperature outside the range of temperatures at which crystal lattice vacancies are relatively mobile in the single crystal silicon, the cooling rate does not appear to significantly influence the precipitating characteristics of the wafer and thus, does not appear to be narrowly critical.

Conveniently, the cooling step may be carried out in the same atmosphere in which the heating step is carried out. Alternatively, the wafer may be cooled in an oxygen containing atmosphere. After the wafer has been cooled it is ready for continued wafer processing and use in an electronic device manufacturing process.

The concentration of oxygen precipitates is primarily a function of the heating step and secondarily a function of the cooling rate. In general, the concentration of oxygen precipitates increases with increasing temperature and increasing annealing times in the heating step with precipitate densities in the range of about 1×10⁷ to about 5×10¹⁰ precipitates/cm³ being routinely obtained.

The depth from the front and back surfaces of oxygen precipitate-free material (denuded) zones is primarily a function of the cooling rate through the temperature range at which crystal lattice vacancies are relatively mobile in silicon. In general, the depth decreases with decreasing cooling rates with denuded zone depths of at least about 20, 30, 40, 50, 70 or even 100 microns being attainable. Significantly, the depth of the denuded zone is essentially independent of the details of the electronic device manufacturing process and, in addition, does not depend upon the out-diffusion of oxygen as is conventionally practiced.

While the heat treatments employed in this process may result in the out-diffusion of a small amount of oxygen from the surface of the front and back surfaces of the wafer, the wafer bulk at depths of at least 5 microns from the wafer surface will have a substantially uniform oxygen concentration. Nevertheless, a denuded zone of substantially greater depth can be formed as a consequence of the cooling step which caused the formation of a non-uniform distribution of crystal lattice vacancies in the wafer.

Unlike prior methods used to form denuded zones, it is unnecessary to subject the single crystal silicon to a high temperature step to cause the outdiffusion of oxygen in regions near the surface of the silicon. Such high temperature steps when carried out for the sole purpose of forming a denuded zone add significant cost to the silicon wafer. Thus, the wafer of the present invention will have a denuded zone and a substantially uniform oxygen concentration as a function of depth from the silicon surface. For example, the wafer will have a uniform concentration of oxygen from the center of the wafer to regions of the wafer which are within about 15 microns of the silicon surface, more preferably from the center of the silicon to regions of the wafer which are within about 10 microns of the silicon surface, even more preferably from the center of the silicon to regions of the wafer which are within about 5 microns of the silicon surface and most preferably from the center of the silicon to regions of the wafer which are within 3 microns of the silicon surface. In this context, substantially uniform oxygen concentration shall mean a variance in the oxygen concentration of no more than about 50%, preferably no more than about 20% and most preferably no more than about 10%.

In conjunction with the creation of a denuded zone as described above and also in accordance with the present invention, the Bulk Micro-Defect Density (BMD Density, referred to hereinafter as oxygen precipitate concentration) within the semiconductor wafers can be engineered by adjusting the parameters of the annealing operation.

Parameters such as ramp up/down rates, hold times and temperatures can be manipulated to establish internal gettering in the wafer bulk to getter unwanted metallic impurities early in the device fabrication process.

Finally, the front surface of the semiconductor wafer having the epitaxial silicon layer is subjected to a final “touch” or “flash” polishing operation to improve sub-micron roughness and substantially eliminate minor defects on the epitaxial layer. The final polishing also maintains the wafer flatness while improving the smoothness of the front surface of the semiconductor. This type of final polish is known to those skilled in the art and generally removes less than about 1 micron of material, preferably between about 0.25 microns and about 0.5 microns of material from the front surface of the semiconductor wafer in a chemical/mechanical polishing process using, for example, a dilute ammonia stabilized colloidal silica slurry and conventional polishing equipment. A preferred ammonia stabilized colloidal silica slurry is Glanzox 3900, which is commercially available from Fujimi Incorporated of Aichi Pref. 452, Japan. Glanzox 3900 has a silica content of from 30 about 8% to about 10% and a particle size of from about 0.025 to about 0.035 microns. If the ammonia stabilized silica slurry is not diluted prior to use, the polished wafer will not be as smooth as a wafer treated with a diluted slurry. A dilution of about one part silica slurry to about 10 parts deionized water is preferred. After final polishing the semiconductor wafer has a TTV of between about 0.1 microns and about 1 micron, preferably between about 0.1 microns and about 0.5 microns, the STIR (using the front surface as the reference plane) is between about 0.1 microns and about 0.2 microns, preferably between about 0.1 microns and about 0.15 microns, and the average front surface roughness, R_{A} is about 5 angstroms over an area of about 1 millimeter by about 1 millimeter.

### OxyQen Precipitate Nucleation and Stabilization

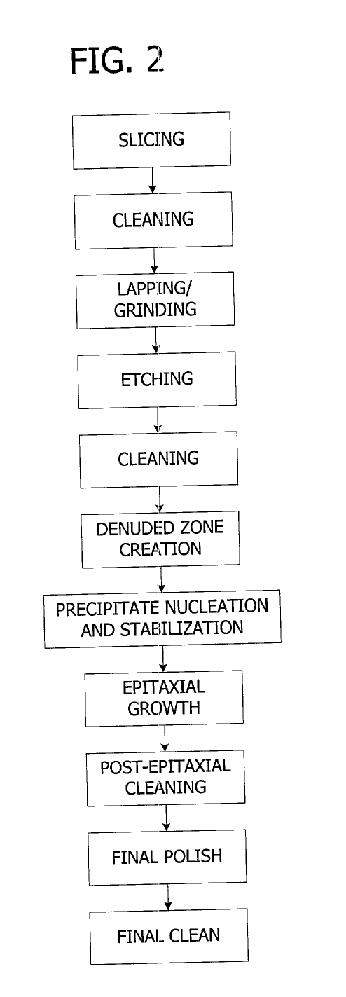

In general, an epitaxial wafer may be subjected to the denuded zone creation process, either before or after the epitaxial deposition. In a second embodiment shown in FIG. 2, the denuded zone creation process is carried out before the epitaxial deposition. Moreover, oxygen precipitates are grown (nucleated) and stabilized according to the vacancy profile after the precipitating heat treatment process, and prior to the epitaxial deposition such that they survive the epitaxial deposition process. It is also contemplated to stabilize the precipitates even if the precipitating heat treatment is performed after the epitaxial deposition.

In general, the oxygen precipitate nucleation and stabilization heat treatment of the present invention causes oxygen precipitation nuclei to form according to the vacancy profile in the ideal precipitating wafer. That is, the oxygen precipitation nuclei will form in the bulk region, a region having a high concentration of vacancies, and will not form in the surface layer, a region having a low concentration of vacancies. In one embodiment, the oxygen precipitation nuclei are stabilized such that they are capable of surviving subsequent high temperature thermal anneals at temperatures not in excess of 1150° C. In another embodiment, the oxygen precipitate nuclei in the bulk region grow, eventually precipitating out of the solid solution, and forming oxygen precipitates in the bulk region while maintaining a denuded zone in the surface layer. The oxygen precipitates may be grown to a size sufficient to produce intrinsic gettering. In still another embodiment, the wafers are subjected to an epitaxial deposition process after the oxygen precipitate nucleation and stabilization process to produce and epitaxial wafer. Advantageously, Epitaxial deposition processes typically require heating the wafer substrate to a temperature not in excess of 1150° C. Accordingly, oxygen precipitates formed and stabilized according to the process of the present invention are capable of surviving typical epitaxial deposition processes thus resulting in an epitaxial wafer having intrinsic gettering.

It should be noted, that although the resulting wafer is particularly useful as a starting wafer for an epitaxial deposition processes, the wafer may be similarly used as a starting wafer for any high temperature process capable of dissolving conventionally produced oxygen precipitate nuclei, such as for example, RTO and RTN processes or in any device manufacturing process requiring both a denuded zone and intrinsic gettering. That is, the present invention further provides for a process wherein the oxygen precipitate nucleation and stabilization heat treatment produces oxygen precipitates at a desired concentration and size to produce intrinsic gettering, or such that they are capable of growing to a size sufficient to produce intrinsic gettering in a subsequent device manufacturing process. Stated differently, if the thermal conditions for a particular device manufacturing process are known, the oxygen precipitate nucleation and stabilization heat treatment can be designed to grow the precipitates to an initial size and concentration such that, upon being subjected to all or a portion of the thermal conditions of the device manufacturing process, they grow to a size sufficient to produce intrinsic gettering. For device manufacturing process which do not include thermal conditions capable of producing significant growth in the oxygen precipitates, the oxygen precipitate nucleation and stabilization heat treatment can be designed to grow the precipitates to an initial size and concentration such that they produce intrinsic gettering prior to the device manufacturing process. Thus, the wafer may be used in any device manufacturing process wherein a wafer having both a denuded zone and intrinsic gettering is desired and is particularly advantageous in device manufacturing processes which are otherwise incapable of forming both a denude zone and a bulk region containing oxygen precipitates sufficient in size and concentration to produce intrinsic gettering.

Oxygen precipitates may be grown and stabilized according to the vacancy profile of an ideal precipitating wafer by subjecting the wafer to an oxygen precipitate nucleation and stabilization heat treatment wherein the wafer is heated to a temperature and for a time period sufficient for the oxygen interstitial atoms to diffuse, agglomerate at vacancy cites to form oxygen precipitate nuclei which then grow to a critical size sufficient to survive a subsequent high temperature process at temperatures not in excess of 1150° C. For example, a heat treatment of 2 to 4 hours at. a temperature of 800° C. has generally found to be sufficient to allow the oxygen atoms to diffuse and combine at crystal lattice vacancies to form oxygen precipitate nuclei that are stable at process temperatures of not in excess of 1150° C.

The process for precipitating oxygen and growing the precipitates to a critical size sufficient to survive a high temperature process such as an epitaxial deposition is mostly limited by the diffusion rate of the oxygen interstitial atoms. In a simple, diffusion limited growth model, the precipitate radius, R, after the wafer is subjected to an isothermal heat treatment for time t at a temperature T is given by:

R=[W_{OX}×(Cᵢ−C₁*)×D(T)×t]^{½} (1)

Semiconductors and Semimetals, Vol. 42, OxVqen in Silicon, ed. F. Shimura, Academic Press, 1994, p. 367). Wherein, Cᵢ is the initial interstitial oxygen concentration, Cᵢ* is the equilibrium interstitial oxygen concentration at temperature T, W_{OX} is the volume of an SiO₂ molecule, D(T) is the diffusivity of interstitial oxygen in Si at temperature T, and t is the heat treatment time at temperature T. Thus for a given interstitial oxygen concentration, the precipitate radius is proportional to the diffusion length, L_{diff}, such that:

L_{diff.}(D(T)×t)^{½} (2)

wherein, D(T)and t are as defined above. The diffusivity of interstitial oxygen, D(T), is calculated by the equation:

D(T)=(7.8×10⁸ mm²/min) (e^{-29,333/T}) (3)

wherein, T is the heat treatment temperature in degrees Kelvin and D(T) has the units mm²/min.

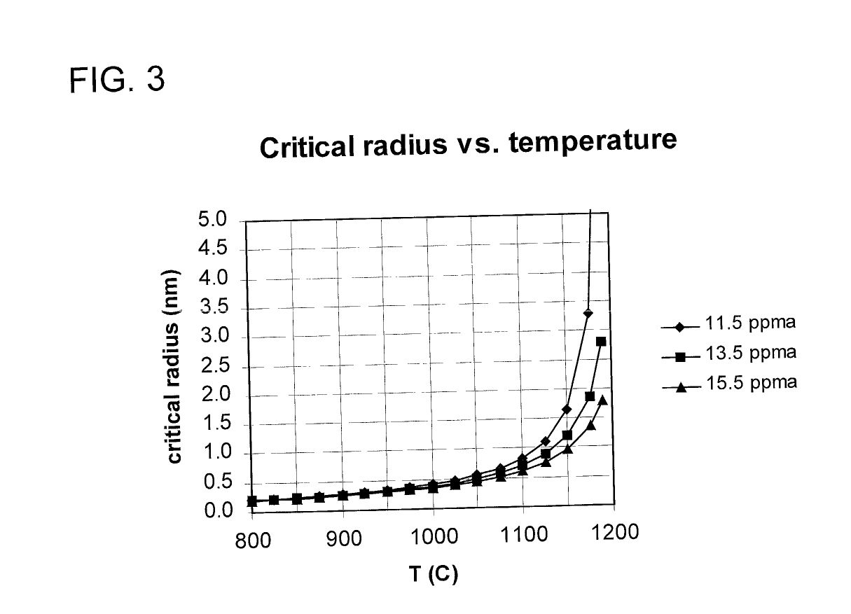

To survive a high temperature process such as an epitaxial deposition, the oxygen precipitate should have a minimum radius, R, greater than a critical radius, R_{C}, which depends on the process temperature to which the wafer will be subjected and wafer interstitial oxygen concentration Semiconductors and Semimetals, Vol. 42, Oxygen in Silicon, ed. F. Shimura, Academic Press, 1994, pp. 363-367). For example, as shown in FIG. 3, for any process temperature ranging from about 800° C. to about 1200° C. there exist a critical radius below which the precipitate may dissolve during the process. Furthermore, as shown in FIG. 3 the critical radius generally increases with decreasing interstitial oxygen concentration. Thus, for wafers which may be subjected to a subsequent high temperature process wherein the temperature is at least about 1000° C., the oxygen precipitates are preferably grown during the oxygen precipitate nucleation and stabilization process such that they have a radius of at least about 0.5 nm and more preferably at least about 1 nm or greater. Wafers which may be subjected to a subsequent high temperature process wherein the temperature is at least about 1100° C. are preferably grown, during the oxygen precipitate nucleation and stabilization process, such that they have a radius of at least about 0.5 nm and more preferably at least about 1 nm or greater. Finally, wafers which may be subjected to a subsequent high temperature process wherein the temperature is at least about 1150° C. are preferably grown, during the oxygen precipitate nucleation and stabilization process, such that they have a radius of at least about 0.5 nm and more preferably at least about 1 nm, more preferably at least about 1.5 nm and most preferably at least about 2 nm or greater.

In addition, the oxygen precipitates may be grown to a size significantly greater than the minimum radius required to stabilize the precipitates and may even be grown to a size sufficient to produce the gettering effect without requiring additional growth during subsequent device manufacturing processes. That is, the oxygen precipitates may be grown such that the radius is as large as 3 nm, 5 nm, 10 nm, 25 nm and even as high as 50 nm or greater.

In general, the concentration of oxygen precipitates formed by the process of the present invention is preferably from about 10⁷ precipitates/cm³ to about 10⁹ precipitates/cm³. The concentration of the oxygen precipitates typical is inversely proportional to the size of the precipitates such that process conditions which cause the formation of large oxygen precipitates typically results in a smaller precipitate concentration than process conditions which cause the formation of smaller precipitates. Thus, to maintain a sufficient concentration of oxygen precipitates with a size sufficient to produce intrinsic gettering, the oxygen precipitates are preferably grown to a radius of from about 5 nm to about 15 nm and more preferably from 8 nm to about 10 nm.

A critical diffusion length, L_{C}, required to form and stabilize the oxygen precipitates may be determined such that for a given oxygen precipitate nucleation and stabilization heat treatment temperature, the time period required to allow the oxygen interstitial atoms to diffuse and combine to form oxygen precipitates and grow to a size sufficient to survive the epitaxial process may be calculated. That is, the critical diffusion length may be determined by the equation:

L_{C}=(D(T)×tₘᵢₙ)^{½}=R_{C}/[W_{OX}×(Cᵢ−Cᵢ*)]^{½} (4)

wherein L_{C}is the critical diffusion length in microns, D(T) is the interstitial oxygen diffusivity having the units mm²/min and tₘᵢₙ is the minimum heat treatment time, in minutes, required to grow and stabilize the oxygen precipitates. Thus, from equations (1) through (4), the minimum time, tₘᵢₙ required to grow and stabilize oxygen precipitates to a size sufficient to survive thermal treatments at a given temperature can be calculated as a function of the oxygen precipitate nucleation and stabilization heat treatment. temperature, and the critical diffusion length according to the following equation:

tₘᵢₙ=L_{C}²/[(7.8×10⁸ mm²/min) (e^{-29,333}/T)] (5)

Thus, a desired radius is selected and equations (1) through (4) are used to determine the total diffusion length required to produce the selected radius for a given oxygen interstitial concentration. For example, to grow the oxygen precipitates having a radius; of about 2.6 nm requires thermal process conditions capable of producing a diffusion length of about 0.5 mm. Accordingly, ideal precipitating wafers subjected to an oxygen precipitate nucleation and stabilization heat treatment. producing a diffusion length of 0.5 mm will form a concentration of oxygen precipitates having a concentration profile corresponding to the vacancy profile with the precipitates having a size of about 2.6 nm and thus being capable of surviving an epitaxial deposition process at temperatures not greater than 1150° C.

In one embodiment, the oxygen precipitate nucleation and stabilization heat treatment is an isothermal heat treatment wherein the wafer is heated to a temperature of from about 750° C. to about 850° C. and more preferably about 800° C. The duration of the isothermal oxygen precipitate nucleation and stabilization heat treatment necessary to provide a sufficient diffusion length at a given heat treatment temperature may be determined using Equation (5). For example, to produce a critical diffusion length of about 0.5 mm, the duration of the isothermal oxygen precipitate nucleation and stabilization heat treatment is preferably about 5 hours at a temperature of about 750° C., and preferably about 4 hours at a temperature of about 800° C.

Oxygen precipitate nucleation and stabilization in an ideal precipitating wafer comprises two stages; a vacancy-enhanced nucleation of small oxygen clusters, followed by their subsequent growth to precipitates large enough to survive subsequent high temperature thermal treatments or even large enough to getter metal impurities.

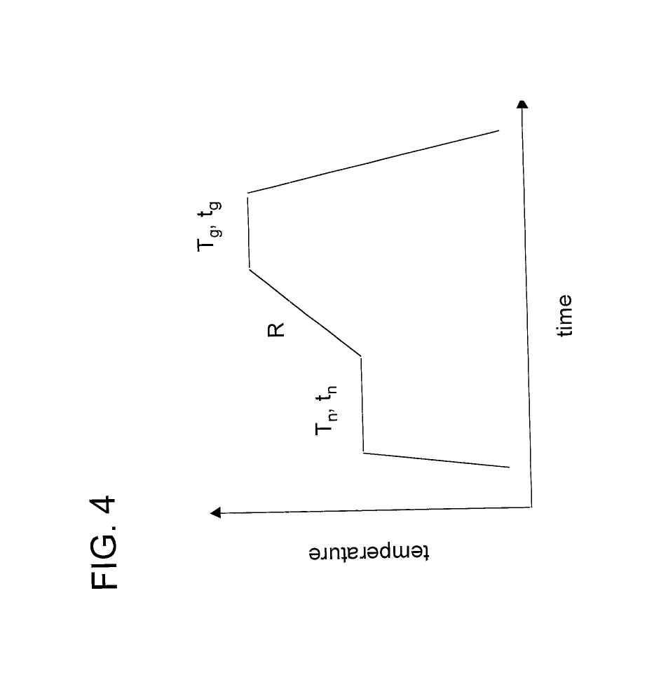

Preferably, the oxygen precipitate nucleation and stabilization heat treatment is a non-isothermal heat treatment as shown schematically in FIG. 4. The non-isothermal heat treatment comprises first thermally treating the wafer at a nucleation temperature, Tₙ, of from about 750° C. to about 900° C., more preferably from about 800° C. to about 850° C. and most preferably from about 800° C. to about 825° C. The wafer is maintained at the nucleation temperature for a time period, tₙ, which is sufficient to allow oxygen atoms to cluster together to form oxygen precipitate nuclei. The wafer is preferably maintained at the nucleation temperature for a time period, tₙ, of at least about 15 minutes, more preferably at least about 30 minutes and most preferably at least about 60 minutes, and in some applications may be maintained at the nucleation temperature for a time period, tₙ, of at least about 2 hours or longer.

The temperature of the wafer is then increased or ramped up to a growth temperature, T_{g}, with the rate at which the temperature is ramped up being controlled such that the ramp rate, ΔT, is sufficiently slow to allow the oxygen precipitate nuclei grow such that the radius of the oxygen precipitate nuclei remain larger than the critical radius. That is, as the temperature is increased, the critical radius increases. If the temperature is increased such that the critical radius is greater than the radius of the oxygen precipitate nuclei, the nuclei will begin to dissolve. Thus, the temperature is increased at a ramp rate, ΔT, which allows the nuclei to grow such that the radius of the oxygen precipitates is maintained above the critical radius. That is, the temperature is preferably increased at a ramp rate, ΔT, less than about 10° C./min, more preferably from about 1° C./min to about 5° C./min, more preferably about 2° C./min to about 4° C./min and most preferably from about 3° C./min to about 4° C./min.

The growth temperature, T_{g}, is preferably from about 850° C. to about 1150° C., more preferably from about 900° C. to about 1100° C. and most preferably from about 900° C. to about 1000° C. The wafer is maintained at the growth temperature for a time period, t_{g}, required to grow the oxygen precipitates to the desired size. That is, the wafer is maintained at the growth temperature for a time period sufficient to ensure the total diffusion length for the oxygen precipitate nucleation and stabilization heat treatment necessary to grow the precipitate to the desired size is achieved.

The total diffusion length of the non-isothermal oxygen precipitation heat treatment can be determined by calculating the approximate diffusion length for each stage of the heat treatment process and adding each stage in quadrature to obtain the total diffusion length. The diffusion length of the isothermal stages may be determined using equations (2) and (3). The temperature ramping stage may be determined using numerical or series expansion methods to integrate equations (2) and (3) over the range of temperatures over which the ramp occurs. In this way, t_{g} for a particular growth temperature may be determined to produce a desired total diffusion length while taking into consideration the growth effects of the previous nucleation and ramped temperature stages. That is, the diffusion length associated with the first thermal treatment and ramp stages may be determined and subtracted from the total diffusion length in quadrature to determine the diffusion length required for the growth stage. A growth temperature is then selected and the growth time required to produce the required diffusion length is calculated using equation (5).

Thus, the duration of the growth stage may vary considerably based on thermal conditions selected for both the nucleation stage and ramp stage and the desired size for the oxygen precipitates. In fact in cases where the desired radius of the oxygen precipitate nuclei is only slightly in excess of the critical radius, R_{C}, the wafer may be immediately cooled upon reaching the growth temperature such that t_{g} is effectively 0 minutes; whereas, in cases where the desired radius is well in excess of the critical radius, i.e., a radius of 3 nm, 5 nm, 10 nm, 25 nm and even as high as 50 nm or greater, the wafer may be maintained at the growth temperature for considerably longer periods of time, i.e. a duration of about 30 minutes, about 1 hour, about 2 hours, about 4 hours and even as long as 8 hours or more.

As shown in Table I a non-isothermal oxygen precipitate nucleation and stabilization heat treatment comprising first annealing the wafer at a nucleation temperature of 800° C. for 1 hour, ramping the temperature from about 800° C. to about 900° C. at a rate of about 4° C./minute and then immediately cooling the wafer produced a wafer having a concentration of oxygen precipitation nuclei similar to the isothermal oxygen precipitate nucleation and stabilization heat treatment at a temperature 800° C. for 4 hours with an overall cycle time of about 50% of the isothermal process.

TABLE I
Oxygen Precipitate Concentration formed by both an
isothermal anneal and a non-isothermal anneal isothermal
anneal having approximately the same diffusion length.

| Oxygen precipitate | Oxygen | |
|---|---|---|
| nucleation and | precipitates | Total Cycle |
| stabilization Conditions | per cm³ | Time [hr] |
| 800 ° C. for 4 h | 4.70E + 09 | 4.54 |
| 800° C. for 1 h + 4° C./min | 3.84E + 09 | 2.29 |
| ramp to 900° C., then cool | | |

Semiconductor wafers prepared in accordance with the processes of the present invention may be utilized as replacements for many semiconductor wafers currently being used by device manufacturers. More specifically, the low-cost semiconductor wafers of the present invention can be directly substituted for higher cost semiconductor wafers now being utilized by device manufacturers. In a preferred embodiment of the present invention, an epitaxial silicon layer containing either an n(−)type or a p(−)type dopant is grown on an etched semiconductor substrate of similar or substantially identical resistivity; i.e., a p(−) epitaxial layer on a p(−) substrate, a p(+) epitaxial layer on a p(+) substrate, an n(−) epitaxial layer on an n(−) substrate, or an n(+) epitaxial layer on an n(+) substrate. These combinations of like resistivities between the epitaxial layer and the substrate are similar to existing polished wafers currently utilized by device manufacturers.

Semiconductor wafers produced in accordance with this embodiment of the present invention have a high tolerance for epitaxial thickness variation across the front surface of the wafer as the resistivities of the epitaxial layer and the substrate are similar and thus reduce the effect of epitaxial layer thickness non-uniformity. As such, up to about a 10% variation in epitaxial layer thickness across the substrate surface will not adversely effect the overall performance of the semiconductor wafer.

To further increase the value of the low cost replacement semiconductor wafer described above utilizing a doped epitaxial layer grown on a p(−) or n(−) substrate of similar or substantially identical resistivity, the wafer may be subjected to a process for creating a denuded zone (i.e. a non-uniform depth distribution of oxygen precipitates) of sufficient depth and a wafer bulk containing a sufficient density of oxygen precipitates for internal gettering during device manufacturing as described above. In p(−) and n(−) substrates, there may not be sufficient dopant in the substrate during device manufacturing to create sufficient gettering of impurities. If the wafer is subjected to a denuded zone creation process, intrinsic gettering of the wafer during device manufacturing is significantly enhanced and resulting losses by device manufacturers due to metals contamination is decreased.

In a further embodiment of the present invention, an epitaxial silicon layer containing a p(−)type dopant is grown on an etched semiconductor substrate of different resistivity; i.e., on a p(+) semiconductor wafer substrate. The combination p(−) epitaxial layer on a p(+) substrate results in a highly doped wafer substrate containing dopant precipitation in the wafer bulk that provides internal gettering of contaminants such as metals. The lightly doped epitaxial layer is substantially oxygen and precipitate free and devices can be fabricated thereon. During device manufacturing, there is sufficient dopant present in the highly doped substrate to getter contaminants from the epitaxial layer and the wafer itself. This combination of a lightly doped epitaxial layer on a heavily doped substrate may also be a suitable replacement for wafers currently being utilized by device manufacturers. Note that it is also contemplated to deposit a n(−) epitaxial layer on a n(+) wafer substrate.

In view of the above, it will be seen that the several objects of the invention are achieved and other advantageous results attained.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description or shown in the accompanying drawings shall be interpreted as illustrative and not in a limiting sense.

What is claimed is:

1. A process for manufacturing a semiconductor wafer sliced from a single crystal ingot, the wafer having a front surface and a back surface, the process comprising:
etching the semiconductor wafer to reduce damage on the front and back surfaces of the semiconductor wafer;
growing a layer of epitaxial silicon on the etched front surface of the semiconductor wafer to improve the surface roughness of the front surface of the semiconductor wafer; and
final polishing the front surface of the epitaxial wafer to improve the surface roughness of the front surface of the semiconductor wafer.

2. A process as set forth in claim 1 wherein the etching operation is performed such that average front surface roughness is between about 50 nanometers and about 100 nanometers over an area of 1 millimeter by 1 millimeter.

3. A process as set forth in claim 1 wherein the growing operation includes growing a layer of epitaxial silicon less than 10 microns thick.

4. A process as set forth in claim 1 further comprising cleaning the front surface of the semiconductor wafer to remove particulate matter, contaminants and a silicon oxide layer from the front surface after etching but prior to growing the epitaxial silicon layer.

5. A process as set forth in claim 5 wherein the cleaning operation includes a wet cleaning operation to remove metals and particulate matter and a heating operation to remove the silicon oxide layer.

6. A process as set forth in claim 1 further comprising subjecting the semiconductor wafer to a process for creating a denuded zone within the wafer.

7. A process as set forth in claim 6 further comprising subjecting the wafer to a process for nucleating and stabilizing oxygen precipitates after creating the denuded zone and prior to growing the layer of epitaxial silicon.

8. A process as set forth in claim 7 wherein the process for creating the denuded zone includes rapid thermal annealing and the process for nucleating and stabilizing oxygen precipitates includes converting vacancy concentrations created by the rapid thermal annealing into oxygen precipitate nuclei of sufficient size to survive the temperature of the epitaxial growing operation.

9. A process as set forth in claim 1 wherein the growing operation comprises growing an epitaxial silicon layer containing a dopant of substantially identical resistivity as the semiconductor substrate.

10. A process as set forth in claim 1 wherein the growing operation comprises growing an epitaxial silicon layer containing an n(−)type dopant on an etched n(−)type semiconductor substrate.

11. A process as set forth in claim 1 wherein the growing operation comprises growing an epitaxial silicon layer containing a p(−)type dopant on an etched p(−)type semiconductor substrate.

12. A process as set forth in claim 1 wherein the growing operation comprises growing an epitaxial silicon layer containing a dopant of substantially different resistivity than the semiconductor substrate.

13. A process as set forth in claim 1 wherein the growing operation comprises growing a p(−) epitaxial layer on a p(+) semiconductor wafer substrate.

14. A process for manufacturing a semiconductor wafer sliced from a single crystal ingot, the wafer having a front surface and a back surface, the process comprising:
etching the semiconductor wafer to reduce damage on the front and back surfaces of the semiconductor wafer;
cleaning the etched front surface of the semiconductor wafer to remove metals, particulate matter and a silicon oxide layer therefrom;
growing a layer of epitaxial silicon on the cleaned and etched front surface of the semiconductor wafer to improve the surface roughness of the front surface of the semiconductor wafer;
subjecting the semiconductor wafer to a process for creating a denuded zone within the wafer; and
final polishing the front surface of the epitaxial wafer to improve the surface roughness of the front surface of the semiconductor wafer.
